(19) United States
(12) Patent Application Publication
(10) Pub. No.: US 2009/0238069 A1
(43) Pub. Date: Sep. 24, 2009

(54) DEVICE AND METHOD FOR CONTROLLING PROGRAM STREAM FLOW

(75) Inventors: Bo-Ting Lin, Tainan (TW); Shih-Ta Hsu, Tainan (TW)

Correspondence Address: BAKER & MCKENZIE LLP;PATENT DEPARTMENT, 2001 ROSS AVENUE, SUITE 2300, DALLAS, TX, 75201, US

(73) Assignee: HIMAX TECHNOLOGIES LIMITED, Tainan (TW)

(21) Appl. No.: 12/051,751

(22) Filed: Mar. 19, 2008

(51) Int. Cl. G01R 31/08

(52) U.S. Cl. 370/235

(57) ABSTRACT

A device for controlling program stream flow is described. The device is capable of saving power during computation. The device may include a de-multiplex unit and a direct memory access controller. The de-multiplex unit, for de-multiplexing a plurality of data, may include a request module for generating a request signal. The direct memory access controller is for receiving the request signal. The direct memory access controller obtains a plurality of data from a bus and sends the plurality of data to the de-multiplex unit according to the request signal.

### BACKGROUND OF THE INVENTION

1. Field of the Invention

The invention relates to a flow controlling method. More particularly, the invention relates to a device and a method for controlling a program stream flow.

2. Description of the Related Art

A Central Processing Unit (CPU), also commonly known as a processor, is a description of a certain class of logic machines that can execute computer programs. Some specific programs of software are executed to obtain system clock reference (SCR) information from a packer header of the program stream, thereby controlling the flow of a program stream. Such software controls the flow to prevent the flow from being FIFO overflowed or from having an FIFO underflow. However, such software also increases the CPU usage.

Thus, there is a need in the art for a device and/or a method for reducing the CPU usage.

### SUMMARY OF THE INVENTION

One embodiment of the invention is a device for controlling the program stream flow. The device, capable of saving power during computation, comprises a de-multiplex unit and a DMAC (direct memory access controller). The de-multiplex unit, for de-multiplexing a plurality of data, comprises a request module for generating a request signal. The DMAC is for receiving the request signal. The DMAC obtains a plurality of data from a bus and sends the plurality of data to the de-multiplex unit according to the request signal.

The device of the invention achieves a flow control of a program stream by incorporating the direct memory access controller with the hardware. This incorporation reduces CPU usage, but maintains the original flexibility.

Another embodiment of the invention is a method for controlling the program stream flow. The method, capable of saving power during computation, comprises steps as follows: a request signal form a request module of a de-multiplex unit is sent to a DMAC. A plurality of data is obtained from a bus by the DMAC. The plurality of data is sent from the DAMC to the de-multiplex unit. The plurality of data is de-multiplexed by the de-multiplex unit. The plurality of data is stored to a memory.

The method achieves a flow control of a program stream by incorporating a direct memory access controller with the hardware. This incorporation reduces CPU usage, but maintains the original flexibility.

### BRIEF DESCRIPTION OF THE DRAWINGS

FIG. 1 is a device for controlling the program stream flow in accordance with an embodiment of the invention.

FIG. 2 is a flow chart illustrating a method for controlling the program stream flow in accordance with an embodiment of the invention.

FIG. 3 is a de-multiplex unit in accordance with an embodiment of the invention.

FIG. 4 is a timing diagram in accordance with an embodiment of the invention.

### DETAILED DESCRIPTION OF THE PREFERRED EMBODIMENT(S)

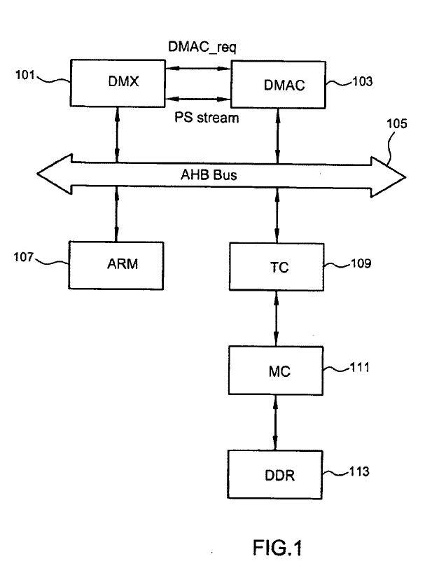

Referring to FIG. 1, a device for controlling the flow of program stream in accordance with an embodiment of the invention is shown. The device, capable of saving power during computation, may include a de-multiplex unit (DMX) 101 and a DMAC (direct memory access controller) 103.

The de-multiplex unit 101 may de-multiplex a plurality of data. The plurality of data may be a plurality of data-output-lines. In this case, the de-multiplex unit 101 may de-multiplex the plurality of data by, for example, taking a single input that selects one of the data-output-lines and connects the single input to the selected output line.

The de-multiplex unit 101 may include a request module for generating a request signal (DMAC_req). The DMAC 103 may receive the request signal (DMAC req). The DMAC 103 obtains a plurality of data from a bus 105 and sends the plurality of data (PS_stream) to the de-multiplex unit 101 according to the request signal (DMAC req).

The bus 105 may be an AHB (Advanced High-performance bus). An AHB is a bus protocol introduced in AMBA Specification version 2 published by ARM Ltd company. A simple transaction on the AHB consists of an address phase and a subsequent data phase (without wait states: only two bus-cycles). Access to the target device is controlled through a multiplexer, thereby admitting bus-access to one bus-master at a time.

The device may further include a DDR (memory) 113, a MC (memory controller) 111 and a TC (traffic controller) 109. The DDR 113 may store the plurality of data. The plurality of data may comprise a plurality of packets. The plurality of packets may comprise at least one PES (Packetized Elementary Stream) packet.

PES is defined by MPEG communication protocol which is an Elementary Stream (ES) that is packetized by adding a packet header to every×number of bytes. The size of a PES packet is usually the size of the elementary stream packet plus the size of the PES header, but there are exceptions especially with audio elementary streams.

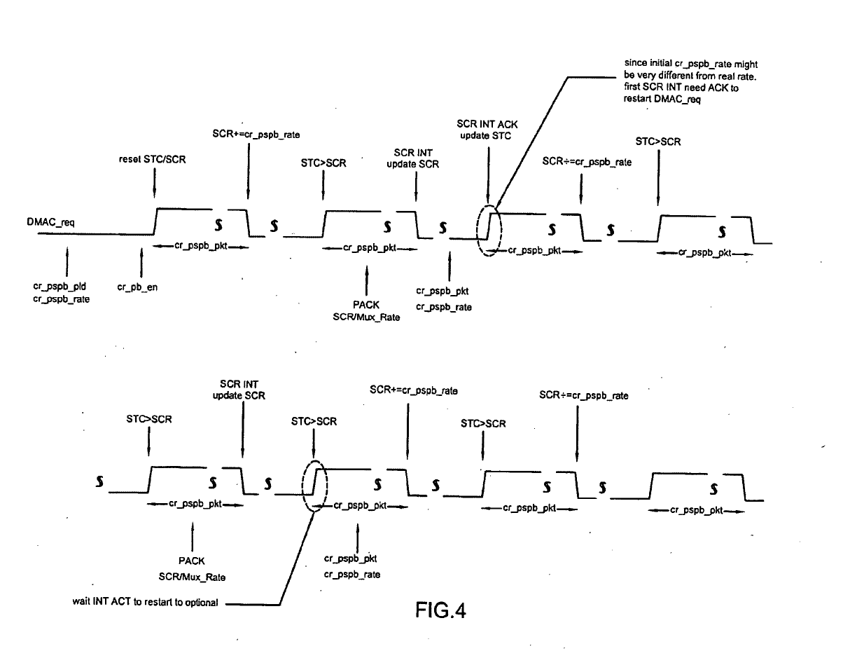

The ESs are encoded in relation to a single encoder “system time clock” (STC). Likewise, the decoding and synchronized presentation of the ESs are ideally synchronized in relation to the same encoder STC. Thus, the decoder must be able to recover the original encoder STC to decode each ES and present each decoded ES in a timely and mutually synchronized fashion. To that end, samples of the STC, called system clock references (SCRs), are inserted selectively into systems layer streams. According to the first embodiment of the present invention, the SCRs may be inserted as shown in FIG. 4, which schematically shows a timing diagram. Referring to FIG. 4, the abbreviations are as follows:

cr_pd_cn: playback enable.

cr_pspb_pkt: number of bytes to read every time STC>SCR

cr_pspb₁₃ rate: SCR step to control playback rate, (system_clock_frequency×cr_pspb pkt)/(program_mux_rate×50)

The MC 111, coupled to the memory, may control the DDR 113. The TC 109, coupled to the AHB bus and MC 11, may control the flow of the data. The DDR 113 may be a DDR SDRAM (double-data-rate synchronous dynamic random access memory). DDR SDRAM is a class of memory integrated circuit used in computers. It achieves greater bandwidth than the preceding single data rate SDRAM by transferring data on the rising and falling edges of the clock signal (double pumped). Effectively, it doubles the transfer rate without increasing the frequency of the memory bus.

The device for controlling the flow of program stream may further comprise a processing unit, for example an ARM (Advanced RISC Machine) unit 107. An ARM is a 32-bit RISC processor developed by ARM Limited that is widely used in a number of embedded designs. Because of their power saving features, ARM CPUs are dominant in the mobile electronics market, where low power consumption is a critical design goal. The ARM unit 107 may be used to process a plurality of codes from, for example, the bus 105.

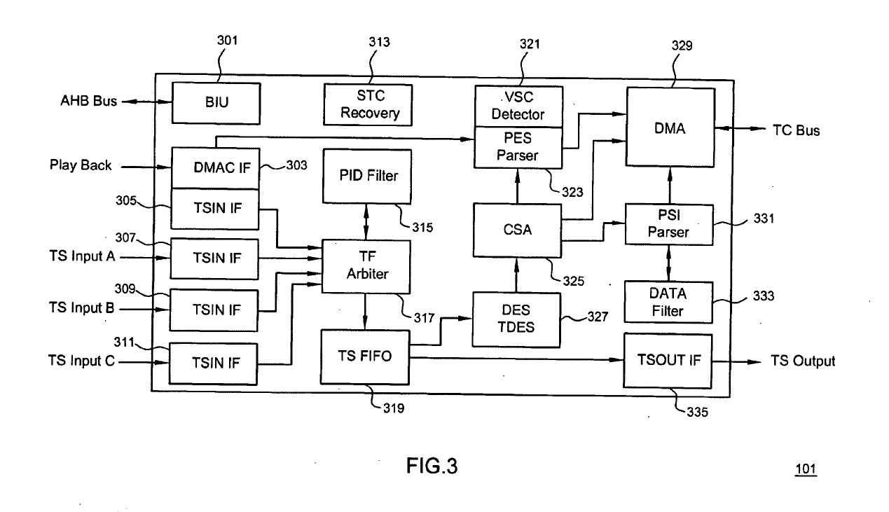

Referring to FIG. 3, there is shown a de-multiplex unit in accordance with an embodiment of the invention. The de-multiplex unit 101 may include a plurality of input interfaces 303, 305, 307, 309, 311, a filter 315, a FIFO (first-in-first-out) unit 319, a plurality of parsers 323, 331 and a DMA (direct memory access) unit 329.

FIFO is an abstraction in ways of organizing and manipulating data relative to time and prioritization. This expression describes the principle of a queue processing technique or servicing conflicting demands by ordering process by first-come, first-served (FCFS) behavior: what comes in first is handled first, what comes in next waits until the first is finished, etc.

The plurality of input interfaces 303, 305, 307, 309, 311 may receive the plurality of data individually. The filter 315 may select and extract a plurality of packets out of the plurality of data. The FIFO (first-in-first-out) unit 319 may store the plurality of packets. The plurality of parsers 323, 331 may decode the plurality of packets.

The DMA unit 329 may store a plurality of desired memory block from the plurality of decoded packets. The DMA unit 329 is included in the de-multiplex unit 101 to provide memory arrangement.

Functions of the blocks of the de-multiplex unit 101 are described as follows.

BIU (Bus Interface Unit) 301: control registers setting.

DMAC IF (the input interface 303): interface to DMAC on system AHB bus, used for TS/PS input.

TSIN IF (the input interface 305, 307, 309 or 311): TS input serial/parallel conversion and synchronization.

STC Recovery 313: recovery STC from extracted PCR/SCR.

PID Filter 315: extracted and selected TS packets by PID.

TF arbiter 317: TS FIFO arbiter, used to arbitrate TSIN IFs to TS FIFO.

TS FIFO (the FIFO unit 319): TS packets temporarily storage FIFO.

VSC Detector 321: Video Start Code detector for AV sync.

PES Parser 323: PES Packet decoder.

CSA unit 325: DVB Common Descrambler.

DES/TDES unit 327: copy protection decrypter.

DMA unit 329: internal DMA engine.

PSI Parser 331: PSI packet decoder.

DATA Filter 333: section data filter.

TSOUT IF 335: TS output serial/parallel conversion and synchronization.

The filter 315 may be a PID (program identifier) filter 315. The PID filter 315 may extract and select the plurality of packet by PID. The de-multiplex unit 101 may further include a DES (data encryption standard)/TDES (triple data encryption standard) unit 327 coupled to the FIFO unit 319. The DES /TDES unit 327 may decipher the plurality of packets.

The DES may be a cipher (a method for encrypting information) selected as an official Federal Information Processing Standard (FIPS) for the United States in 1976, and which has subsequently enjoyed widespread use internationally. The algorithm was initially controversial, with classified design elements, a relatively short key length, and suspicions about a National Security Agency (NSA) backdoor. The TDES is a block cipher formed from the Data Encryption Standard (DES) cipher by applying it three times.

The de-multiplex unit 101 may further comprise a CSA (common scrambling algorithm) unit 325. CSA is the encryption algorithm used in the digital television broadcasting for encrypting video streams. CSA was specified by European Telecommunications Standards Institute (ETSI) and adopted by the Digital Video Broadcast (DVB) consortium in May 1994. The CSA unit 325, coupled to the DES/TDES unit, may be used to descramble a DVB.

The DVB is a suite of internationally accepted open standards for digital television. DVB standards are maintained by the DVB Project, an industry consortium with more than 270 members, and they are published by a Joint Technical Committee (JTC) of ETSI, European Committee for Electrotechnical Standardization (CENELEC) and European Broadcasting Union (EBU). The interaction of the DVB sub-standards is described in the DVB.

The plurality of parsers 323, 331 may comprise at least one PES (packetized elementary stream) parser 323. The PES parser 323, coupled to the CSA unit 325, may be used to decode at least one PES.

The device of the present invention achieves a flow control of a program stream by incorporating a direct memory access controller with the hardware. This incorporation reduces CPU usage, but maintains the original flexibility. This incorporation also controls the flow to prevent the flow from being FIFO overflowed or from having an FIFO underflow.

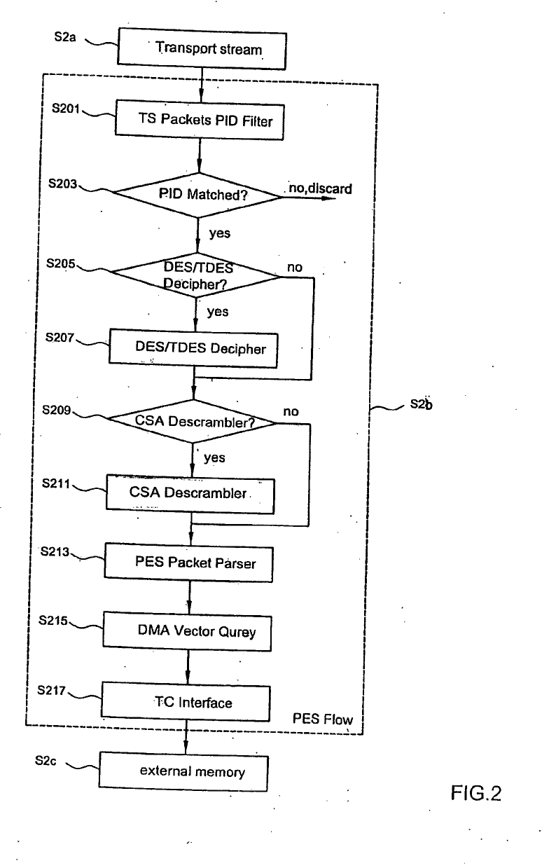

FIG. 2 is a flow chart illustrating a method for controlling the flow of program stream in accordance with an embodiment of the invention. The method of FIG. 2 could be implemented using, for example, the device shown in FIG. 1 and the de-multiplex unit 101 shown in FIG. 3.

Referring to FIG. 1, FIG. 2 and FIG. 3, a request signal from a request module of a de-multiplex unit 101 is sent to the DMAC 103. A plurality of data is obtained from the bus 105 by the DMAC 103. Preferably, the bus 105 is an AHB bus.

As shown in FIG. 2, in a step S2a, the plurality of data from the DAMC 103 is sent to the de-multiplex unit 101. In a step S2b, the plurality of data is de-multiplexed by the de-multiplex unit 101. In a step S2c, the plurality of data are stored to the memory 113.

The plurality of data may comprise a plurality of packets. The plurality of packets may comprise at least one packetized elementary stream packet.

The method may further comprise step S217 and S2c. In the step S217, the flow of the data is controlled by the TC (traffic controller) 109. In the step S2c, the plurality of data is stored to the memory 113 and the memory 113 is controlled by a MC 111.

Unlike the prior art, the method achieves a flow control of a program stream by incorporating a direct memory access controller with the hardware. This incorporation reduces CPU usage, but maintains the original flexibility. A timing diagram in this invention is shown in FIG. 4.

The method may further comprise steps S201-S203, a step S213 and a step S215. In the steps S201-S203, a plurality of packets out of the plurality of data is selected and extracted by the filter 315.

In the step S213, at least one PES packet of the plurality of packets is decoded by at least one PES parser 323. A plurality of desired memory blocks may be from at least one PES packet. In the step S215, the plurality of desired memory blocks may be stored by the DMA unit 329.

The method may further comprise steps S205, S207. In the steps S205, S207, the plurality of packets is deciphered by the DES/TDES unit 327.

The method may further comprise steps S209, S211. In the steps S209, S211, the DVB is descrambled by a CSA unit.

Preferably, the filter 315 is a PID filter. The PID filter extracts and selects the plurality of packet by PID. The memory 113 is, for example, a DRAM (dynamic random access memory).

The method may further comprise a step of processing a plurality of codes by the ARM unit 107. The codes may be from, for example, the bus 105 of FIG. 1.

Thus, by incorporating the device and/or the method in accordance with the invention, a flow control of a program stream is achieved. The device and/or the method reduce CPU usage, but maintain the original flexibilities. This incorporation also controls the flow to prevent the flow from being FIFO overflowed or from having an FIFO underflow.

While the invention has been described and illustrated in connection with preferred embodiments, many variations and modifications as will be evident to those skilled in this art may be made without departing from the spirit and scope of the invention, and the invention is thus not to be limited to the precise details of methodology or construction set forth above.

What is claimed is:

1. A device for controlling a program stream flow, capable of saving power during computation, comprising:
a de-multiplex unit, for de-multiplexing a plurality of data, wherein the de-multiplex unit comprises a request module for generating a request signal, wherein the de-multiplex unit comprising:
a plurality of input interfaces to receive the plurality of data individually;
a filter to select and extract a plurality of packets out of the plurality of data;
a FIFO ( first-in-first-out) unit to store the plurality of packets;
a plurality of parsers to decode the plurality of packets; and
a DMA (direct memory access) unit to store a plurality of desired memory block from the plurality of decoded packets; and
a DMAC (direct memory access controller), for receiving the request signal, wherein the DMAC obtains a plurality of data from a bus and sends the plurality of data to the de-multiplex unit according to the request signal

2. The device of claim 1, wherein the bus is a AHB (Advanced High-performance) bus.

3. The device of claim 2, further comprising:
a memory for storing the plurality of data;
a MC (memory controller), coupled to the memory, for controlling the memory; and
a TC (traffic controller), coupled to the AHB bus and memory controller, for controlling the flow of the data.

4. The device of claim 3, wherein the memory is a DDR SDRAM (double-data-rate synchronous dynamic random access memory).

5. The device of claim 1, further comprising a ARM( Advanced RISC Machine) unit which is coupled to the AHB bus, for processing a plurality of codes of the device.

6. The device of claim 1, wherein the filter is a PID (program identifier) filter, in which the PID filter extracts and selects the plurality of packet by PID.

7. The device of claim 1, wherein the de-multiplex unit further comprises a DES (data encryption standard)/TDES (triple data encryption standard) unit, coupled to the FIFO unit, for deciphering the plurality of packets.

8. The device of claim 7, wherein the de-multiplex unit further comprises a CSA (common scrambling algorithm) unit, coupled to the DES/TDES unit, used for descrambling the DVB (digital video broadcast)

9. The device of claim 8, wherein the plurality of parsers comprises at least one PES (packetized elementary stream) parser that couples to the CSA unit and is used for decoding at least one PES packet of the plurality of packets.

10. A method for controlling a program stream flow, capable of saving power during computation, comprising:
sending a request signal form a request module of a de-multiplex unit to a DMAC;
obtaining a plurality of data from a bus by the DMAC;
sending the plurality of data from the DAMC to the de-multiplex unit;
de-multiplexing the plurality of data by the de-multiplex unit; and
storing the plurality of data to a memory.

11. The method of claim 11, wherein the bus is an AHB bus.

12. The method of claim 12, further comprising:
controlling the flow of the data by a TC (traffic controller); and
controlling the memory by a MC (memory controller).

13. The method of claim 11, further comprising:
selecting and extracting a plurality of packets out of the plurality of data by a filter;
decoding at least one PES packet from the plurality of packets by at least one PES parser; and
storing a plurality of desired memory block from the plurality of decoded packets by a DMA unit.

14. The method of claim 13, further comprising:
deciphering the plurality of packets by a DES/TDES unit.

15. The method of claim 14, further comprising:
descrambling a DVB by a CSA unit.

16. The method of claim 14, wherein the filter is a PID filter, in which the PID filter extracts and selects the plurality of packet by PID.

17. The method of claim 11, wherein the memory is a DRAM (dynamic random access memory).

18. The method of claim 11, further comprising:
processing a plurality of codes by a ARM( Advanced RISC Machine) unit.
